(19) United States
(12) Patent Application Publication
(10) Pub. No.: US 2025/0309905 A1
(43) Pub. Date: Oct. 2, 2025

(54) METHOD TO IDENTIFY, ISOLATE AND REMOVE THE SOURCE(S) OF JITTER AFFECTING REFERENCE CLOCK AND DATA USING TIME INTERVAL ERROR

(71) Applicant: Tektronix, Inc., Beaverton, OR (US)

(72) Inventors: Madhusudan Acharya, Bengaluru (IN); Shubha B, Bengaluru (IN); Niranjan Hegde, Bengaluru (IN); Krishna N H Sri, Bengaluru (IN)

(21) Appl. No.: 19/085,177

(22) Filed: Mar. 20, 2025

(30) Foreign Application Priority Data
Mar. 28, 2024 (IN) 202421025358

(51) Int. Cl. H03M 1/06; H03M 1/10; H03M 1/12

(52) U.S. Cl. CPC H03M 1/0626; H03M 1/1071; H03M 1/1255

(57) ABSTRACT

A test and measurement instrument includes one or more ports to connect to a device under test (DUT), the DUT having one or more clock signals and one or more power rails, one or more analog-to-digital converters (ADC) to receive a signal from the DUT and convert the signal to waveform data, a user interface to allow a user to input one or more frequency pairs, and one or more processors to: determine a time interval error between a time of received edges and an expected time of the received edges; design a filter based upon start and stop frequencies for each of the one or more frequency pairs; filter the received edges to produce filtered edges; produce corrected clock edges from the filtered edges to produce a clock waveform; and reconstruct data of the waveform using the clock waveform to produce a reconstructed waveform.

### CROSS-REFERENCE TO RELATED APPLICATIONS

This disclosure claims priority under 35 U.S.C. § 119 to Indian Provisional Patent Application No. 20/242,1025358, titled “METHOD FOR IDENTIFY, ISOLATE AND REMOVE THE SOURCE(s) OF JITTER AFFECTING REFERENCE CLOCK AND DATA USING TIME INTERVAL ERROR,” filed on Mar. 28, 2024, the disclosure of which is incorporated herein by reference in its entirety.

### TECHNICAL FIELD

The present disclosure relates to a test and measurement instrument that can identify, isolate, and remove the source(s) of jitter affecting reference clock and data using time interval error.

### BACKGROUND

In high-speed electronic systems, operating frequencies can reach values up to tens of GHz with multiple power rails turning on the different high-speed loads. Because of scaled down supply voltages and high switching speeds, keeping the integrity of power and signal in deep sub-micrometer technologies present challenging tasks for the system designers.

Signal integrity (SI) analysis focuses on the performance of the transmitter, reference clock, channel, and receiver in terms of the bit error rate (BER). Power integrity (PI) focuses on the power distribution network's (PDN's) ability to provide constant, clean power rails and low impedance return paths.

Users may benefit from knowing the interdependencies between PI and SI and whether PI is affecting the signal quality. The PDN (Power Distribution Network) can cause noise and jitter. The circuit design and components such as voltage regulator module, on-chip packaging, pins, traces, vias, connectors affect the impedance of the PDN and hence the quality of the power supplied.

SI and PI groups within a company often work as separate teams, but finding problems associated with high-speed serial jitter requires understanding both on power and signal quality areas, because power rails and serial data exist on the same board designs.

Due to SOC (system on chip) design, there are many circuits on a single chip and these circuits affect the high-speed serial (HSS) section of the SOC. Understanding the effects of each circuit on HSS signal allows identification and removal of the effects of one or multiple circuit components and to observe the impact on the HSS signal and pinpoint the source of jitter.

Power rail output affects reference clock and shows up as power jitter (PJ) and other jitter components on clock or data signals. In chip designs, clock aggressors sweeping across a frequency range can impact the reference clock with higher jitter components. Power supply fluctuations due to the PDN in multi-rail scenario on the load output can result in poor signal quality and can lead to bit errors. This can impact the functioning of high-speed signals. In some cases, eight or more aggressors may act on the clock lane. Pinpointing jitter on the victim clock lane allows the designer to adjust for it.

### BRIEF DESCRIPTION OF ACCOMPANYING DRAWINGS

FIG. 1 shows an example of TIE and peak-to-peak jitter measurements.

FIG. 2 shows a graphic of sources of noise components in a device under test.

FIG. 3 shows effects of power supply noise on the output of a differential driver.

FIG. 4 shows a clock distribution network in a system on a chip (SoC) system with n-clocks.

FIG. 5 shows an embodiment of an interface enabling new measurements and their configuration.

FIG. 6 shows corrected clock edges extracted from high-speed data resulting from the embodiments.

FIG. 7 shows an embodiment of a flowchart of a method of producing adjusted clock edges to account for power supply induced jitter.

FIG. 8 shows a reference clock and corrected time interval error (TIE) used in the embodiments to reconstruct the clock edges.

FIG. 9 shows a zoomed in version of the TIE trends before and after filtering.

FIG. 10 shows an example of TIE spectra showing 100 KHz sinusoidal component.

FIG. 11 shows TIE with a 100 KHz component removed by application of the embodiments.

FIG. 12 shows an Eye width improvement by application of the embodiments.

FIG. 13 shows TIE spectra filtered at two frequency pairs.

FIG. 14 shows resulting signals from removal of clock jitter, and improvement in a TIE histogram.

FIG. 15 shows an embodiment of a test and measurement device.

### DETAILED DESCRIPTION

The embodiments here provide a test and measurement instrument and a method to identify, isolate, and remove power jitter that affects a reference clock. The effect on the reference clock affects the accuracy of the data signal. The embodiments here identify and list the source of jitter using the time interval error (TIE) between the received edges and the expected edges of the clock. The embodiments produce a TIE spectra plot to allow the user to see aggressor components and the frequency components they generate. The embodiments allow the user to specify multiple frequency ranges of the aggressors' signals, such as multiple power rails. The methods of the embodiments so multiple filters can be applied to the signal to remove multiple sources of jitter. For example, using multiple filters can remove different PJ components at different frequencies on the TIE waveform data.

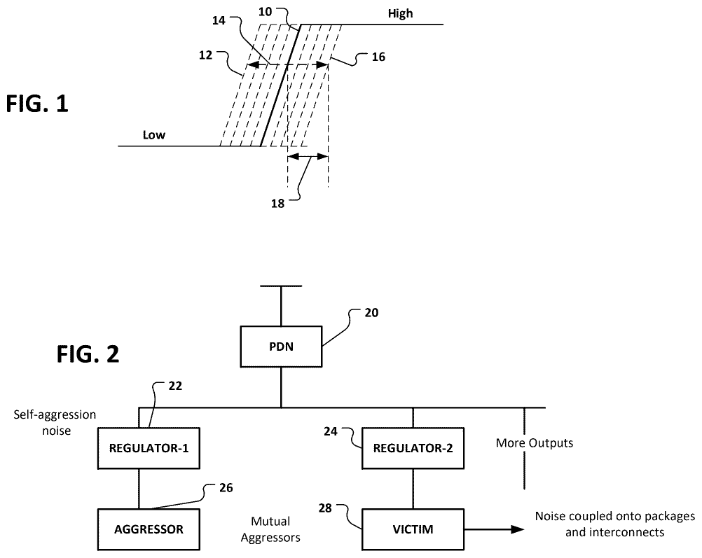

FIG. 1 shows a diagram of time interval errors. The main causes of time interval error result from the changes in output delay and transition edge slope, the shift in bias point of transistors. In FIG. 1, the signal changes from “Low” to “High.” The dark solid line 10 shows the expected edge. The dashed lines, shown by 12 on the Low side are early edges, and the dashed lines shown by 16 are the late edges. The difference between the earliest early edge and the latest late edge, shown by the arrow 14, is the peak-to-peak jitter. TIE is shown by the arrow 18. TIE affects timing margins and can cause violations in setup/hold times of the system.

FIG. 2 shows different kinds of noise components that can affect serial data due to the power supply. The power distribution network (PDN) noise on the power rail can couple into adjacent signal traces through crosstalk. Crosstalk occurs when the noise-induced voltage fluctuations affect neighboring traces. This leads to signal integrity issues. These distortions can impact the reliability and synchronization of data.

As shown in FIG. 2, the voltage regulator modules (VRMs) such a Regulator 1 22 and Regulator 2 24 may experience self-aggression noise. Components that have or cause noise in the discussion herein comprise aggressors, and those that suffer impacts from the noise comprise victims. By “self-aggression” noise, these components may suffer from their own internally generated noise. Aggressors may generate noise that does not affect them but will affect components around them. Aggressor 26 may comprise a power rail, as an example, and component 28 may comprise a clock that suffers from the noise coupled into it from the power rail.

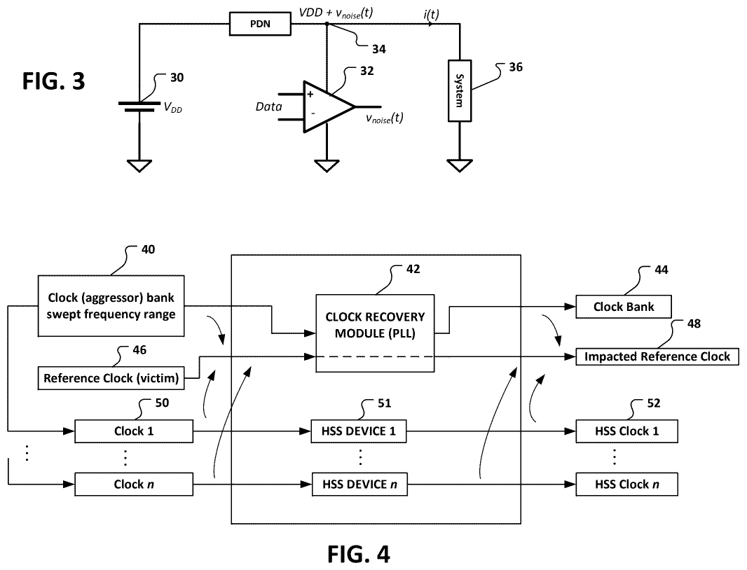

FIG. 3 shows another example of a situation in which power jitter occurs. The system 36 draws current i(t) from the same power source as the differential driver. Because of noise components generated by the PDN, di/dt effects will cause voltage fluctuations at VDD, which affects the output. The noise components v_{Rnoise}(t) and vₙₒᵢₛₑ(t) generated by the PDN lanes and the amplifier 32 impacts the output load of the system.

FIG. 4 shows how a reference clock suffers from these effects. FIG. 4 shows a system reference clock 46 that is a victim of the clock bank 40 with a swept frequency range, and the high-speed serial devices 1 51 through n, and the clocks 1 50 through n. The curved arrows show the coupling effects from these lines to the reference clock line. The reference clock and the clock bank signals enter the clock recovery module, such as a phase-locked loop (PLL). The resulting output reference clock 48 suffers further effects from the HSS clocks 1 52 through n. In one example, the reference clock is 125 MHz, and the clock aggressor is 10 MHz. The 10 MHZ signal will influence the reference clock after 48 after being recovered.

The embodiments herein allow a user running tests on a device under test (DUT), more than likely a system on chip (SoC), to identify aggressors. The instrument has one or more processors that then can filter out the noise components from the aggressors, adjust the reference clock and reconstruct the data stream. The embodiments also provide visualizations to the user to show the noise components and their removal.

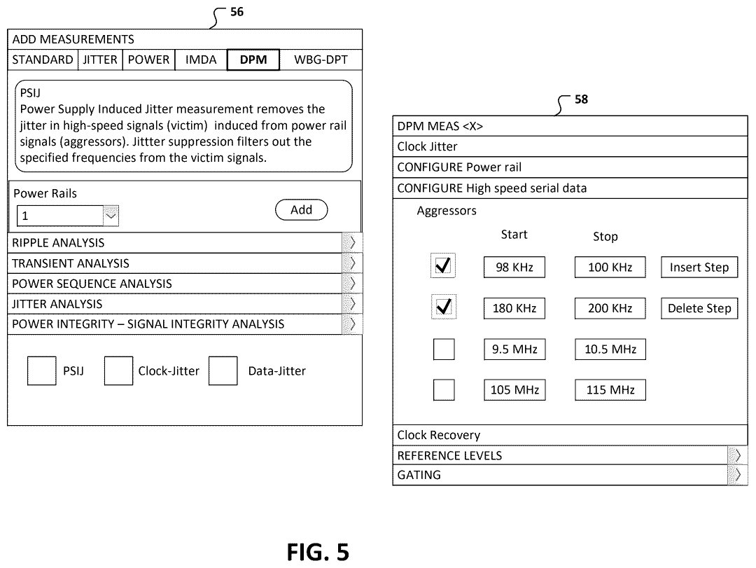

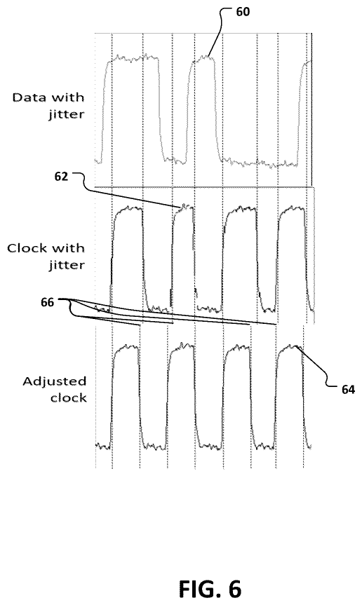

FIG. 5 shows an embodiment of a user interface of a test and measurement instrument that allows a user to specify the aggressors, here in the form of power rails, to allow for the noise components from the aggressors to be removed. On the left side of FIG. 5, at panel 56, the user selects DPM and can specify how many power rails. The panel also provides a description of power jitter (PJ) also referred to as power supply-induced jitter (PSIJ). A second panel 58 allows the user to configure the stop and start frequencies for each power rail. The discussion here refers to the start and stop frequencies of each power rail as “frequency pairs.” The method described below will iterate as many times as there are frequency pairs. After the configuration and the operation of the method, the resulting clock has been adjusted.

FIG. 6 shows a data signal with jitter at 60. The clock with jitter 62 is recovered from the data signal. By filtering the clock edges with jitter, the process produces corrected clock edge. The adjusted clock 64 that will allow the instrument to reconstruct the data signal. The differences between the vertical marker between the clock with jitter 62 and the adjusted clock can be seen at multiple regions 66 as an example.

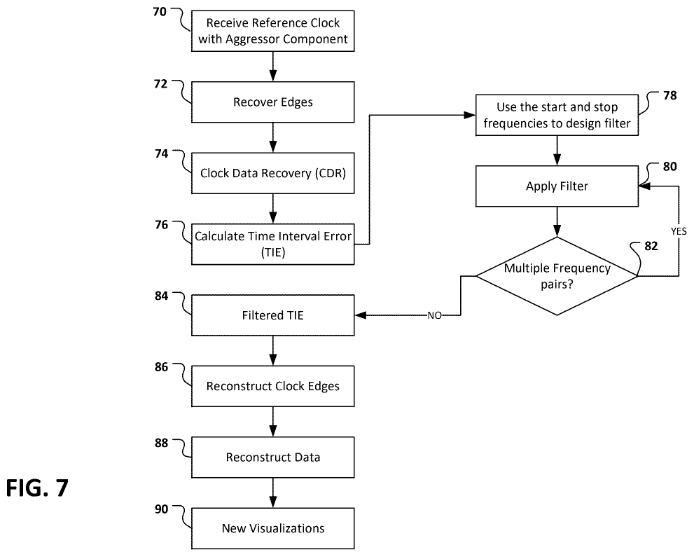

FIG. 7 shows an embodiment of a method to adjust the clock and reconstruct the waveform. The process beings with reception of the reference clock with the aggressor component that affects the reference clock. The edges of the clock are recovered at 72 and the clock and data recovery (CDR) occurs at 74. Clock and data recovery recovers the clock edges from the waveform itself when the data signal does not have an accompanying clock. This recovered clock is used to compute the TIE between the received edges and the recovered clock edges at 76. The TIE here is the original TIE, prior to filtering. In one embodiment, the process interpolates between the filtered edges to obtain the corrected clock edges.

At 78, the method uses the start and stop frequency pairs for at least one aggressor to apply a notch filter at 80 to adjust and correct the clock edges. This process repeats the steps of designing the filter, applying the filter, producing the corrected clock edges, and reconstructing the edges until all frequency pairs have been used. The iterative filtering may comprise a process in which each new filter adjusts the clock edges from the previous step. Once the process has adjusted for all frequency pairs at 82, the process also adjusts the TIE for each edge, as discussed below, this will provide the user with a visualization of the changes in the TIE caused by removing the power jitter.

The process adjusts the clock edges at 86, wherein newCLK[i]=old_edges[i]−filtered TIE[i], where i equals 1 to the number of edges. Using the corrected clock edges, the process then reconstructs the data. In one embodiment, reconstructing the data means each cycle in the data must be zoomed in or zoomed out based upon the adjusted clock edges. To maintain the same sample rate, the data in that cycle must be resampled.

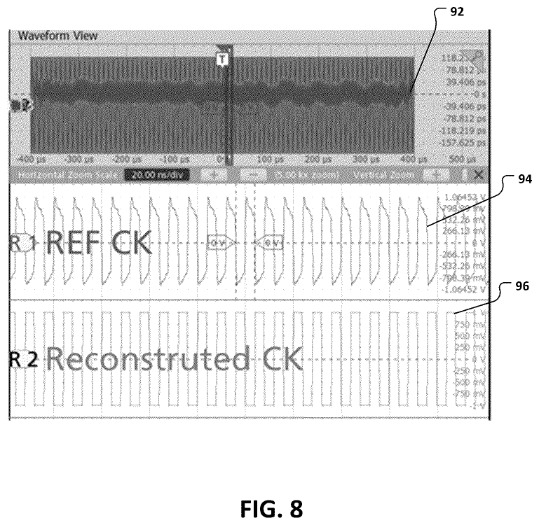

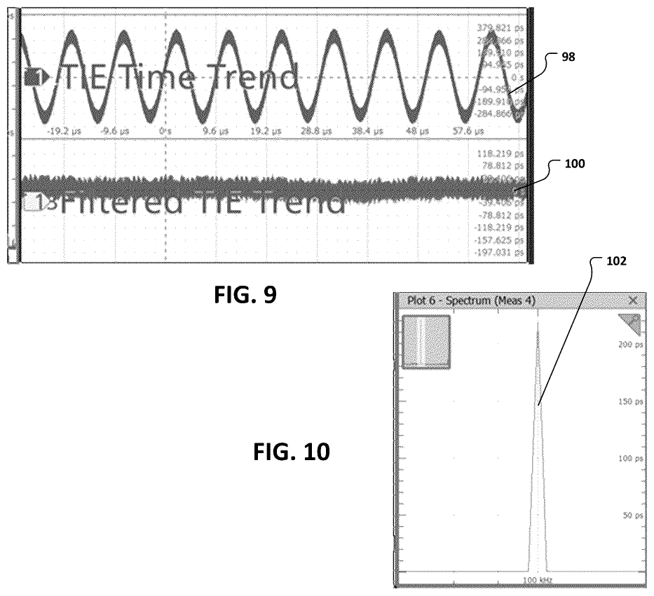

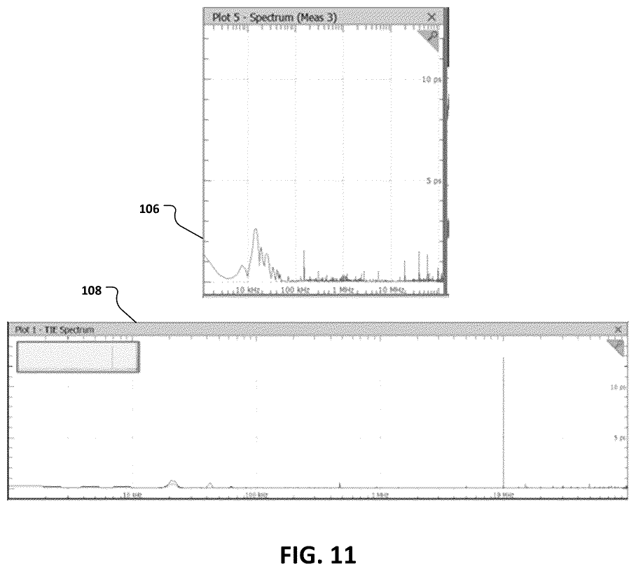

FIGS. 8-14 show results of this process. FIG. 8 shows a waveform 92 and the original reference clock 94 and the reconstructed clock 96. These results show significant results. FIG. 9 shows a zoomed in version of the TIE time trend 98 and the filtered TIE trend 100. FIG. 10 shows a TIE spectrum of the signal showing a 100 KHz sinusoidal component 102. FIG. 10 shows the input TIE spectra 106 and the reconstructed TIE spectra 108 after removal of the sinusoidal component.

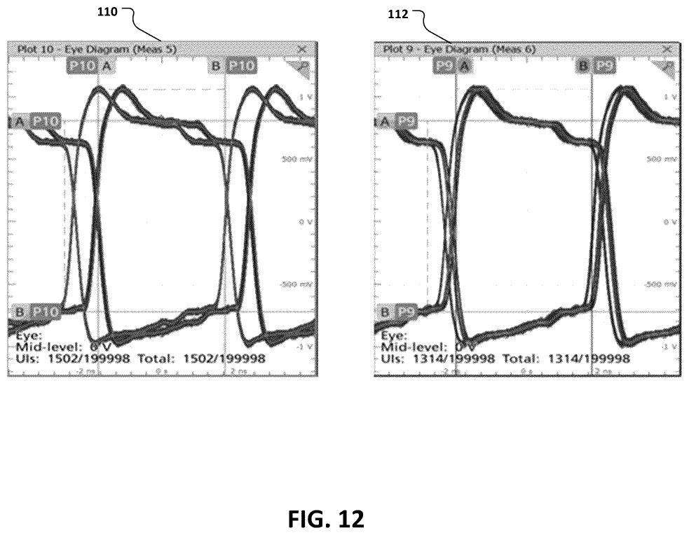

Prior to the removal of the 100 KHz component the power jitter was 649.9 ps. After removal, the power jitter measured at 47.05 ps. FIG. 12 shows an increase in the eye width from 3.290 ns at 110, to 3.549 ns at 112.

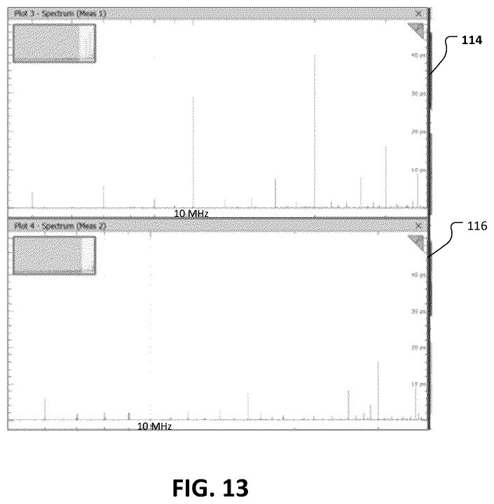

In addition to removing one jitter component, FIG. 13 shows the removal of two frequency pairs, one at 9.5 MHz-10.5 MHz, and one at 19.5 MHz-20.5 MHz.

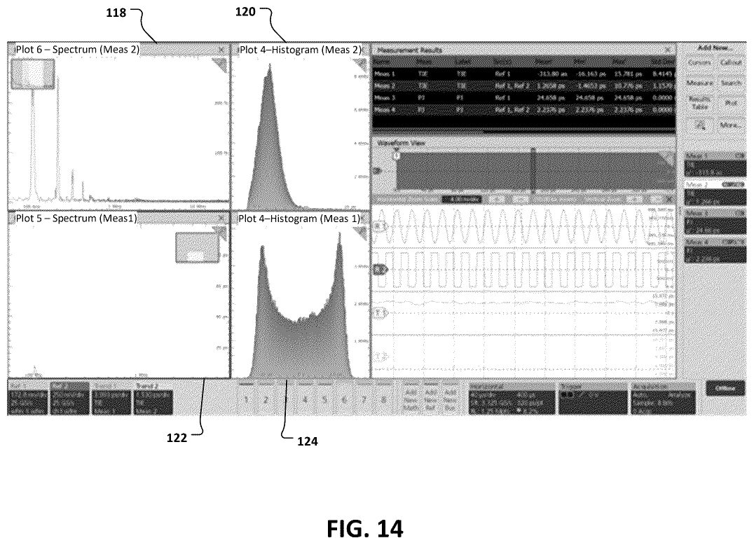

FIG. 14 shows the signal spectrum 118 and histogram 120 prior to removal of the power jitter, and the spectrum 122 and histogram 124 after removal. A once can see the TIE histogram has moved from deterministic, based upon the jitter inputs, to Gaussian.

Providing the user the ability to see the TIE spectra before and after applications of the filter(s) side by side or otherwise together on the user interface acts as a powerful validation during the process. The instrument can display these improved results compared to the previous waveform for all the jitter components, such as total jitter, power jitter (PJ), deterministic jitter (DJ) and random jitter (RJ).

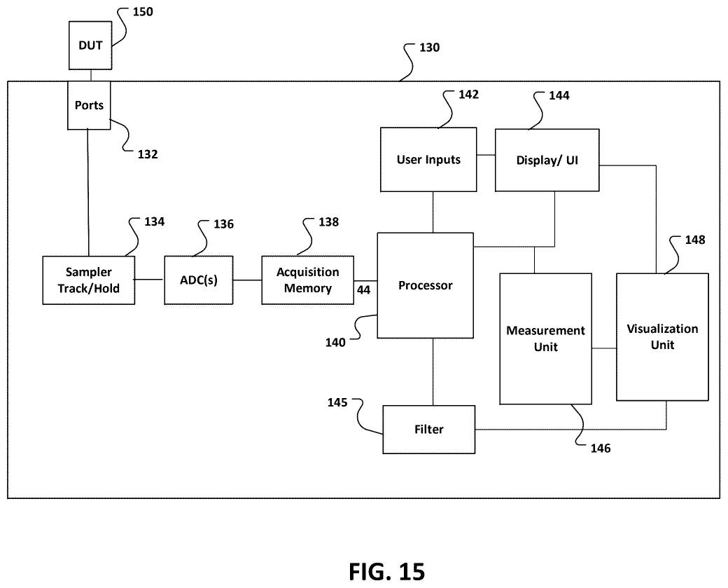

FIG. 15 a block diagram of a test and measurement instrument 130, such as an oscilloscope, for implementing the embodiments herein. The instrument 130 may be an example of the measurement instrument described above. The instrument 130 includes one or more test ports 132 that receives signals of any electrical signal. Port 132 may include receivers, transmitters, and/or transceivers. Test ports 132 receive signals from an attached device, such as a DUT 150, a circuit, a discrete device or set of devices, or other object being tested, through probes or a text fixture, as examples. In some embodiments the DUT 150 is a HSS data-generating device with its power rails as well as HSS data coupled to the test ports 132. Each input port 130 may represent a channel of the instrument 130. As described above, one or more power rails from the DUT 132 may be coupled to the instrument 130 through one or more channels, and one or more HSS data outputs may be coupled to the instrument 130 through other channels. The input ports 132 connect to one or more processors 140 to process the signals and/or waveforms received at the ports 132. Although only one processor 140 is shown in FIG. 15 for ease of illustration, as will be understood by one skilled in the art, that multiple processors of varying types may be used in combination, rather than a single processor 140.

The input ports 132 and one or more processors 140 may also be connected to a sampler track/hold unit that samples the incoming signals and holds them so the analog-to-digital converters (ADCs) 136 can convert the signal to digital samples to be stored in the acquisition memory 138.

The process 140 may also connect to a measurement unit 146 within the instrument 130. The measurement unit 146 may include individual functions to perform the measurement and correlation operations described above. For instance, the measurement unit 146 can include any component or operation capable of measuring aspects of a signal received via the input ports 132 in either or both of the time and frequency domains. For example, the measurement unit may include functions or processes for measuring ripple, for creating TIE spectra from received HSS data, and for creating spectra from PJ data as described above. Once these measurement functions are complete, the one or more processors 140 may coordinate and evaluate these measurement functions for measurements made from the DUT 150.

A visualization unit 148 assembles various displays generated from measurements and analysis made by the measurement unit 146 and sends them to a display 144 for showing on the instrument 130. In some cases, the display may be remote from the instrument 130 itself. Visualizations may include displays such as eye diagrams, one or more spectra, including spectra from two or more measurements that are aligned across the same frequency range, histograms, and data reports that may present measurement data in numerical form. Each of these visualization types are described in detail and illustrated above.

Further, a filtering function 145 may also operate as described above, where the filtering function applies a filter for specific waveforms at particular frequencies. Also as described above, this filtering has the effect of simulating a result of reducing the effect that certain components may have on each other, such as noise on a power rail affecting HSS data.

The one or more processors 140 may be configured to execute instructions from the memory 138, which represents all memory structures in the instrument including operational memory and acquisition memory and may perform any methods and/or associated steps indicated by such instructions, such as displaying values measured to a coupled device according to embodiments of the disclosure. The one or more processors 140 may perform the functions described above with reference to the measurement unit 146, the visualization unit 148, or the filter 145, or the one or more processors 140 may work in conjunction with yet other processors to perform such functions. Memory 138 may be implemented as processor cache, random access memory (RAM), read only memory (ROM), solid state memory, hard disk drive(s), or any other memory type. Memory 130 acts as a medium for storing data, computer program products, and other instructions.

User inputs 142 are coupled to the one or more processors 140. User inputs 142 may include a keyboard, mouse, trackball, touchscreen, and/or any other controls employable by a user with a User Interface on the display 144. The user interface of the display 144 may present the menus such as those shown in FIG. 5 to the user. The display 144 may be a digital screen, or any other monitor to display waveforms, measurements, and other data to a user. The display 144 may also comprise the user input mechanism as in a touch screen. While the components of test instrument 130 are depicted as being integrated within test and measurement instrument 130, it will be appreciated by a person of ordinary skill in the art that any of these components can be external to test instrument 130 and can be coupled to test instrument 130 in any conventional manner (e.g., wired and/or wireless communication media and/or mechanisms). For example, in some embodiments, the display 144 may be remote from the test and measurement instrument 130.

Aspects of the disclosure may operate on a particularly created hardware, on firmware, digital signal processors, or on a specially programmed general-purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the disclosed technologies are provided below. An embodiment of the technologies may include one or more, and any combination of, the examples described below.
Example 1 is test and measurement instrument, comprising: one or more ports to connect to a device under test (DUT), the DUT having one or more clock signals and one or more power rails; one or more analog-to-digital converters (ADC) to receive a signal from the DUT and convert the signal to waveform data comprised of digital samples at a sampling rate; a user interface to allow a user to input one or more frequency pairs; one or more processors configured to execute code that causes the one or more processors to: determine a time interval error between a time of received edges in the signal and an expected time of the received edges; design a filter based upon start and stop frequencies for each of the one or more frequency pairs; filter the received edges to produce filtered edges; produce corrected clock edges from the filtered edges to produce a clock waveform; and reconstruct data of the waveform using the clock waveform of the corrected clock edges to produce a reconstructed waveform.
Example 2 is the test and measurement instrument of Example 1, wherein the start and stop frequencies comprise low and high ends of operating frequencies for each of the one or more power rails.
Example 3 is the test and measurement instrument of either of Examples 1 or 2, wherein the code that causes the one or more processors to filter the received edges comprises code to apply a filter to the received edges for each of the one or more frequency pairs in sequence.
Example 4 is the test and measurement instrument of any of Examples 1 through 3, wherein the code that causes the one or more processors to filter the received edges comprises code to apply multiple filters to remove different power jitter components at different frequencies.
Example 5 is the test and measurement instrument of any of Examples 1 through 4, wherein the code that causes the one or more processors to apply a filter comprises code to apply a notch filter to the received edges.
Example 6 is the test and measurement instrument of any of Examples 1 through 5, wherein the code that causes the one or more processors to reconstruct the corrected clock edges comprises interpolating between the filtered edges to obtain the corrected clock edges.
Example 7 is the test and measurement instrument of any of Examples 1 through 6, wherein the code that causes the one or more processors to reconstruct data of the waveform comprises: zooming in or zooming out the data for each clock cycled depending upon the corrected clock edges; and resampling the data to maintain the original sampling rate.
Example 8 is the test and measurement instrument of any of Examples 1 through 7, wherein the processors are further configured to generate spectral plots of a time interval error before and after removal of one or more power noise components for one or more frequencies and display the spectral plots together on the user interface.
Example 9 is the test and measurement instrument of any of Examples 1 through 8, wherein the processors are further configured to repeat the code the causes the one or more processors to repeat the design step, the filter step, the produce step, and the construct steps for each of the one or more frequency pairs.
Example 10 is a method, comprising: presenting a user interface to a user to allow a user to configure start and stop frequencies as frequency pairs for one or more aggressor signals; receiving a data signal at a test and measurement instrument; determining a time interval error between a time of received clock edges in the data signal and an expected time of the received clock edges; using the start and stop frequencies for each of one or more frequency pairs to define a filter; filtering the received edges using the filter to produce filtered edges; reconstructing corrected clock edges from the filtered edges to produce a clock waveform; and reconstructing data of the waveform using the clock waveform of the corrected clock edges to produce a reconstructed waveform.
Example 11 is the method of Example 10, wherein using the start and stop frequencies to define the filter comprises using the start and stop frequencies to define a notch filter.
Example 12 is the method of either of Examples 10 or 11, wherein reconstructing the corrected clock edges comprises interpolating between the filtered edges to get the corrected clock edges.
Example 13 is the method of any of Examples 10 through 12, wherein reconstructing data of the waveform comprises: zooming in or zooming out the data for each clock cycled depending upon the corrected clock edges; and resampling the data to maintain the original sampling rate.
Example 14 is the method of any of Examples 10 through 13, further comprising generating spectral plots of a time interval error before and after removal of one or more power noise components for one or more frequencies and displaying the spectral plots on the user interface together.
Example 15 is the test and measurement instrument of any of Examples 10 through 14, wherein filtering the received edges comprises applying multiple filters to remove different power jitter components at different frequencies.
Example 16 is the method of any of Examples 10 through 15, further comprising repeating the designing step, the filtering step, the producing step, and the constructing steps for each of the one or more frequency pairs.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific aspects of this disclosure have been illustrated and described for purposes of illustration, it will be understood that various modifications may be made without departing from the spirit and scope of the invention. Accordingly, the invention should not be limited except as by the appended claims.

1. A test and measurement instrument, comprising:
one or more ports to connect to a device under test (DUT), the DUT having one or more clock signals and one or more power rails;
one or more analog-to-digital converters (ADC) to receive a signal from the DUT and convert the signal to waveform data comprised of digital samples at a sampling rate;
a user interface to allow a user to input one or more frequency pairs;
one or more processors configured to execute code that causes the one or more processors to:
determine a time interval error between a time of received edges in the signal and an expected time of the received edges;
design a filter based upon start and stop frequencies for each of the one or more frequency pairs;
filter the received edges to produce filtered edges;
produce corrected clock edges from the filtered edges to produce a clock waveform; and
reconstruct data of the waveform using the clock waveform of the corrected clock edges to produce a reconstructed waveform.

2. The test and measurement instrument as claimed in claim 1, wherein the start and stop frequencies comprise low and high ends of operating frequencies for each of the one or more power rails.

3. The test and measurement instrument as claimed in claim 1, wherein the code that causes the one or more processors to filter the received edges comprises code to apply a filter to the received edges for each of the one or more frequency pairs in sequence.

4. The test and measurement instrument as claimed in claim 1, wherein the code that causes the one or more processors to filter the received edges comprises code to apply multiple filters to remove different power jitter components at different frequencies.

5. The test and measurement instrument as claimed in claim 1, wherein the code that causes the one or more processors to apply a filter comprises code to apply a notch filter to the received edges.

6. The test and measurement instrument as claimed in claim 1, wherein the code that causes the one or more processors to reconstruct the corrected clock edges comprises interpolating between the filtered edges to obtain the corrected clock edges.

7. The test and measurement instrument as claimed in claim 1, wherein the code that causes the one or more processors to reconstruct data of the waveform comprises:
zooming in or zooming out the data for each clock cycled depending upon the corrected clock edges; and
resampling the data to maintain the original sampling rate.

8. The test and measurement instrument as claimed in claim 1, wherein the processors are further configured to generate spectral plots of a time interval error before and after removal of one or more power noise components for one or more frequencies and display the spectral plots together on the user interface.

9. The test and measurement instrument as claimed in claim 1, wherein the processors are further configured to repeat the code the causes the one or more processors to repeat the design step, the filter step, the produce step, and the construct steps for each of the one or more frequency pairs.

10. A method, comprising:
presenting a user interface to a user to allow a user to configure start and stop frequencies as frequency pairs for one or more aggressor signals;
receiving a data signal at a test and measurement instrument;
determining a time interval error between a time of received clock edges in the data signal and an expected time of the received clock edges;
using the start and stop frequencies for each of one or more frequency pairs to define a filter;
filtering the received edges using the filter to produce filtered edges;
reconstructing corrected clock edges from the filtered edges to produce a clock waveform; and
reconstructing data of the waveform using the clock waveform of the corrected clock edges to produce a reconstructed waveform.

11. The method as claimed in claim 10, wherein using the start and stop frequencies to define the filter comprises using the start and stop frequencies to define a notch filter.

12. The method as claimed in claim 10, wherein reconstructing the corrected clock edges comprises interpolating between the filtered edges to get the corrected clock edges.

13. The method as claimed in claim 10, wherein reconstructing data of the waveform comprises:
zooming in or zooming out the data for each clock cycled depending upon the corrected clock edges; and
resampling the data to maintain the original sampling rate.

14. The method as claimed in claim 10, further comprising generating spectral plots of a time interval error before and after removal of one or more power noise components for one or more frequencies and displaying the spectral plots on the user interface together.

15. The test and measurement instrument as claimed in claim 1, wherein filtering the received edges comprises applying multiple filters to remove different power jitter components at different frequencies.

16. The method as claimed in claim 10, further comprising repeating the designing step, the filtering step, the producing step, and the constructing steps for each of the one or more frequency pairs.
